(19) United States
(12) Patent Application Publication
(10) Pub. No.: US 2007/0097648 A1
(43) Pub. Date: May 3, 2007

(54) Method and apparatus for establishing optimal thermal contact between opposing surfaces

(76) Inventors: Kevin Xu, Milpitas, CA (US); Ephraim Suhir, Los Altos, CA (US); Carlos Dangelo, Los Gatos, CA (US)

Correspondence Address: GLENN PATENT GROUP, 3475 EDISON WAY, SUITE L, MENLO PARK, CA, 94025, US

(21) Appl. No.: 11/265,264

(22) Filed: Nov. 1, 2005

(51) Int. Cl. H05K 7/20

(52) U.S. Cl. 361/704

(57) ABSTRACT

To achieve optimal thermal contact between opposing surfaces, it is necessary to align such surfaces so that maximum contact is achieved. In a semiconductor package, it is necessary to align the surface of a semiconductor integrated circuit (IC) and a heat sink surface, where the heat sink contains a nano-composite wire structure. By using a self-aligned structure that forces the alignment of the IC surface and the heat sink, maximum thermal contact between the two surfaces is achieved. The self-alignment of a pressure measurement device for same is also disclosed.

### BACKGROUND OF THE INVENTION

1. Field of the Invention

The invention relates to the alignment of surfaces for the purpose of achieving optimal thermal contact. More particularly, the invention relates to the self-alignment of such surfaces, where one of the surfaces is a nano-composite wire structure.

2. Discussion of the Prior Art

The transfer of heat, to remove heat from a hot surface to the environment, usually for dissipation purposes, may require a mechanism having a sophisticated configuration to ensure that a sufficient amount of heat is dissipated to ensure proper operation of an underlying device. The efficient dissipation of heat from a semiconductor integrated circuit (IC) is of particular interest because as a significant amount of heat is generated from a relatively small surface. This heat must be dissipated to the environment to avoid adverse effects on the semiconductor chip. Such adverse effects include, but are not limited to, complete damage, rendering the device non-functional or destroyed. Therefore, heat dissipation technology has been developed to allow for such heat to dissipate by a variety of types of heat sinks. However, the need to dissipate ever increasing amounts of heat is rapidly growing as ICs increase in operational frequency and size.

One of the challenges involved in heat dissipation is the transfer of heat between two heat conducting surfaces. It is well-known in the art that heat transfer between two plates that are pressed against each other, and that are generally somewhat flat and smooth, occurs in a small contact area, perhaps a few percentage points of the total surface area of the opposing plates. This small area represents the effective area available for thermal transfer. The actual effective contact area depends on characteristics of both surfaces and the material from which the respective surfaces are composed. Among others, effective area depends on hardness, roughness, flatness, pressure, parallelism, surface convexity, and more. In the case of solid-to-solid thermal contact, a small contact area presents a serious problem that prevents effective heat transfer between e.g. two plates which are often of dissimilar materials with different thermal conductivity properties.

To obtain maximum thermal transfer between two opposing surface plates it is necessary to maximize the total area of contact between the two surfaces. Typically the plates are of a hard and non bendable material, made of a crystal or a hard metal, for example, silicon, copper, aluminum, and the like. The plates are pressed against each other by applying a pressure in. the range of, for example, 30-70 pounds per square inch (psi). In a typical case, less than the possible maximum area for thermal contact is obtained. This occurs typically if the opposing surfaces have less than perfect degrees of parallelism, flatness, or micro-roughness, as well as the impact of surface convexity or concavity. To overcome such problems, the existing art of thermal interface contact design teaches the use of grease, such as a thermal interface material (TIM), to achieve a larger thermal contact area. The bond line thickness is in such cases a key parameter to be controlled.

An existing design 100 is shown in FIG. 1, where a heat sink 110 is screwed onto, for example, a printed circuit board (PCB) 150. The bond line thickness of the thermal interface material 130 is controlled by counting the turns of screws 120. Notably, such application of pressure is generally very imprecise, causing the bond line thickness to vary at various positions, thereby impacting the thermal conductivity between the heat sink 110 surface and the heat dissipating surface 140. The area of contact between the heat sink 110 surface and the heat dissipating surface 140 is also shown enlarged in FIG. 1 for illustration purposes. For a thermal interface contact application that uses a solid TIM, a decrease of the effective contact area is observed when the pressure is applied unevenly, resulting in an increase in the thermal interface resistance.

In modern heat sink technology use is made of a thermal interface that comprises a carbon nano-tube array (CNTA) or similar material. In such a case, if the surfaces of the CNTA and the heat dissipating surface are not parallel, the heat conducting advantages of the CNTA rapidly decrease. Furthermore, the CNTA can be severely damaged by the force that applies the pressure between the surfaces.

In view of the limitations of prior-art solutions, it would be advantageous to provide a mechanism for solving the lack of parallelism between surfaces intended for the conduction of heat. It would be further advantageous if such solution is a self-adjusting mechanism that maximizes the surface area contact when two surfaces are brought together for the purpose of thermal transfer from one surface to the other. It would be further advantageous if such a solution would avoid the damages that occur to CNTAs when put in contact between such surfaces.

### SUMMARY OF THE INVENTION

To achieve optimal thermal contact between opposing surfaces, it is necessary to align such surfaces so that maximum contact is achieved. In a semiconductor package, it is necessary to align the surface of a semiconductor integrated circuit (IC) and a heat sink surface, and specifically where the heat sink contains a nano-composite wire structure. By using a self-aligned structure that forces the alignment of the IC surface and the heat sink, maximum thermal contact between the two surfaces is achieved. The self-alignment of a pressure measurement device for same is also disclosed.

### BRIEF DESCRIPTION OF THE DRAWINGS

FIG. 1 is a schematic diagram showing a heat sink being connected to a hot surface mounted on top of a PCB;

FIG. 2 is a schematic diagram showing a structure for self-adjustment of a heat dissipation surface and a hot surface to ensure a high degree of parallelism between the surfaces;

FIGS. 3A-3E show the steps for mounting a heat sink surface on top of a hot surface using the structure for self-adjustment in accordance with the invention; and

FIG. 4 is a schematic diagram showing a device for self-adjustment of a load cell to a first surface of a structure designed in accordance with the invention.

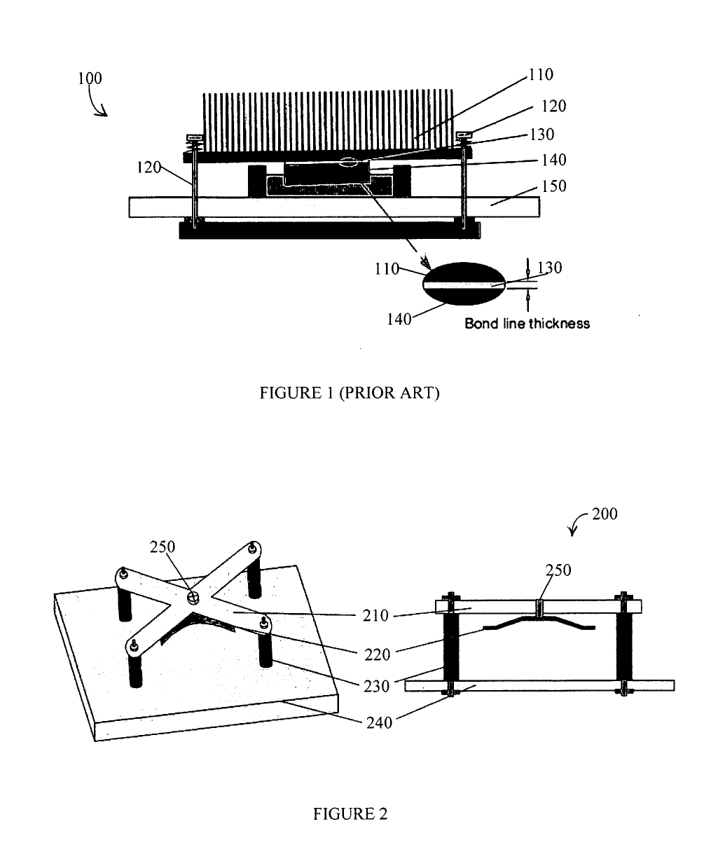

### DETAILED DESCRIPTION OF THE INVENTION

The invention disclosed herein comprises a self adjusting method and apparatus for providing maximum surface area contact when two surfaces are brought together for purposes of enabling thermal transfer from one surface to the other surface. In one preferred embodiment of the invention, one of the surfaces is the back of a semiconductor integrated circuit (IC). The other surface comprises an array of wire-like nano-structures. Such nano-structures may include, but are not limited to, nano-tubes with uneven lengths which touch and bend when compressed against another surface. An advantage of the self-adjusting apparatus is that both surfaces can have a degree of non-parallelism because the self-adjusting structure compensates for such defect. In the invention, the surfaces self-adjust to the maximum possible degree of parallelism when they are pressed against each other with a prescribed pressure.

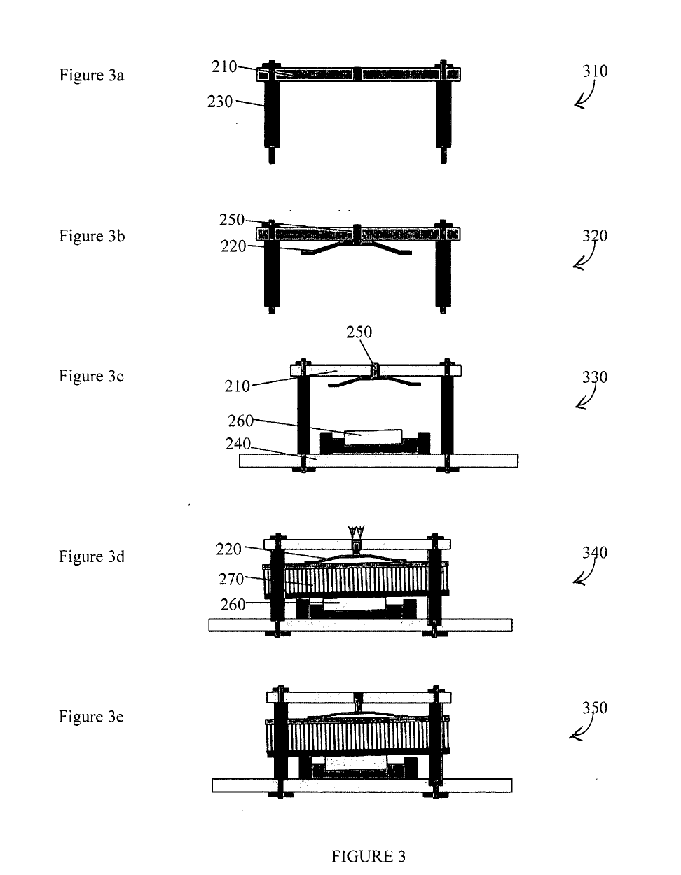

FIG. 2 is a schematic diagram showing a structure 200 for self-adjustment of a heat dissipation surface and a hot surface to ensure a high degree of parallelism between the surfaces. The structure 200 comprises a plurality of rods 230, for example four rods, a mounting structure 210 and a spring 220. The rods 230 and the mounting structure 210 create a supporting platform for the spring 220. The spring 220 is connected to the tip of a top screw 250, allowing it to pivot at essentially a single point. When the spring 220 is put in contact with a heat sink surface, the tightening of the top screw 250 initiates a self-adjustment process, as described in more detail below with respect to FIG. 3.

A person skilled-in-the-art would note that the structure capable of applying pressure on a first surface, for example the heat dissipation surface, by means of a spring, for example the spring 220, may be accomplished by different designs of the spring 220 that is mounted at a center point and enabled to apply pressure onto the first surface by means of tightening of a single screw, thereby enabling the self adjustment of the first surface to a second surface, for example, a hot surface. Hence, the spring 220 may have a form of a plurality of prongs, a disk, and the like, all being connected to the structure via a single screw essentially centered in respect of the plurality of rods 230 of the structure 200. In a preferred embodiment of the invention, there are at least two rods 230. The mounting structure 210 may be formed from a plurality of prongs, or fingers, for example four, connected at one point, as shown in FIG. 2. In another embodiment of the invention, the mounting structure 210 may be a plate of any kind of desired shape. In another embodiment, the spring is designed to conform with the features of the rods 230. For example, in the case of a single dimension (1D) where only two rods 230 are used, an essentially single dimension spring 220 is used, where each prong extends top screw towards its respective rod 230. In yet another embodiment of the invention, a plurality of springs 220 may be connected to a single mounting structure 210. In such a case, the pressure applied by each of the plurality of springs should be essentially equal to ensure the self-alignment properties of the disclosed invention.

FIGS. 3A-3E show steps 310 through 350 for mounting a heat sink surface on top of a hot surface using the structure for self-adjustment in accordance with the invention. Specifically, the attachment method is intended to affix structure 200 and a heat sink 270 onto a PCB 240. As a result of applying pressure on the spring 220 by means of central screw 250, to cause the self-adjustment of heat sink 270 with the hot surface 260. The hot surface 260 may be but is not limited to, the hot surface of a semiconductor IC. The invention achieves the best possible parallelism between the contact surfaces, maximizing contact area, avoiding damage to the CNTAs of the heat sink 270 during the initial contact, and causing the CNTAs to perform in the buckling mode. A detailed discussion of the buckling mode may be found in E. Suhir U.S. patent application Ser. No. 11/207,096 titled An Apparatus and Test Device for the Application and Measurement of Prescribed, Predicted and Controlled Contact Pressure on Wires, assigned to a common assignee (the “'096 patent application”), and which is herein incorporated in its entirety by this reference thereto.

The construction of the structure 200 begins with step 310 where the rods 230 are connected to the top plate 210. In step 320, the spring 220 is attached to the top plate 210 by means of, for example, a screw 250, also referred to herein as the top screw. The spring 220 is mounted to the top plate 210, such that the spring 210 can pivot, allowing the spring to tilt as may be necessary as it comes into contact with the heat sink 270 (discussed further below). In step 330, the structure 200 is mounted to the PCB 240 by means of the rods 230. Preferably, the structure 200 is position above a hot surface to which a heat sink 270 is to be attached in accordance with the invention. In step 340, the heat sink 270 is inserted between the spring 220 and the hot surface 260, while the hot surface 260 may be the hot surface of a semiconductor IC. As shown in FIG. 3C, the steps 330 and onwards, it is possible, and quite common, that the hot surface 260 and the heat sink 270 are not aligned. In step 350, the top screw 250 is tightened for the purpose of causing the self-adjustment. The spring 220 spreads the pressure applied by the top screw 250 but, because of its spring properties, adjusts so that the pressure causes the heat sink 270 to self-adjust with respect to the hot surface 260. The top screw 250 is securely tightened to provide the required compressive force to the spring 220. The application of this force completes the process of self-adjustment, and in the case of the CNTAs, is adjusted to a value that causes the necessary buckling of the nano-tubes, in accordance with the teaching of the '096 patent application.

While the apparatus for the self-adjusting of a first surface to a second surface is described in detail with respect of the self-adjustment of a heat sink to a hot surface of a semiconductor IC, this should not be viewed as a limitation on the general scope of the invention, and it is specifically noted that other implementations required self-adjustment of a first and second surface using a structure essentially in the spirit disclosed herein are specifically envisioned as part of the invention. It should be further noted that multiple springs 220 may be placed on the mounting structure 210. In yet another embodiment of the invention, multiple structures 200 may be used in conjunction with a single heat sink 270.

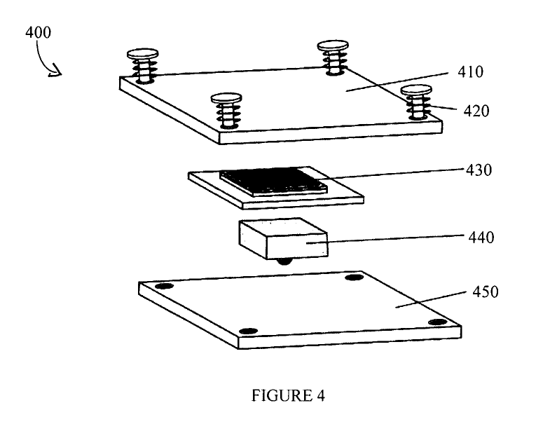

FIG. 4 shows a schematic diagram of a device 400 that causes the self-adjustment of a load cell 440 to a first surface 430 in accordance with the invention. A test pressure device 440 may be, for example, a miniature industrial load cell, such as those provided in the LCDG series by Omega Engineering, Inc, the specification sheets of which are hereby incorporated by reference. The structure 400 comprises an upper plate 410, tightening screws 420, a CNTA 430, a load cell 440, and a lower plate 450. The screws 420 are enabled to tighten the upper plate 410 towards the lower plate 450, with the CNTA 430 and test-pressure device 440 sandwiched in between the upper plate 410 and the lower plate 450. The tightening screws 420 establish and maintain a fully parallel contact. The CNTA 430, typically a sample to be tested for the pressure to be applied to achieve the desired level of buckling, is glued onto load cell 440. In the preferred embodiment of the invention the load cell 440 comprises a rounded bottom 445. Upon application of pressure by the tightening of the screws 420, the rounded bottom 445 of the load cell 440 causes the self-adjustment required to ensure the necessary parallelism between the CNTA 430 and the upper plate 410.

Notably, to achieve the best thermal performance, the following conditions are to be met: the top plate 410 should be parallel to the sample surface, for example the CNTA 430; the top plate 410 should not crush, or otherwise damage the carbon nano-tubes of the CNTA 430 when the upper plate 410 comes into initial contact with the CNTA 430; and, the CNTA 430 should be in buckling mode. Therefore the first step in the assembly process of the structure 400 is to establish an initial contact between the top plate 410 and the CNTA 430. The top plate 410 is typically held on a micro-stage that can be moving on a micro scale in the vertical direction. Pressure is measured in real time through a connection from the load cell 440 to an appropriate reading device (not shown). The top plate 410 is then lowered downwards under the control of, for example, the micro-stage (not shown). As soon as the top plate 410 comes into contact with the CNTA 430, the load cell 440 starts to self-adjust, in accordance with the principles explained above, i.e. due to the round bottom 445 characteristics of the load cell 440.

Once contact is established the second step starts when the pressure reaches a desired level, for example 5 psi. At this stage, the load cell 440 balances itself, and the CNTA 430 is in maximum contact with the top plate 410. This step is intended to transfer the pressure to the CNTA 430, being the sample to be measure. The pressure is transferred from the micro-stage to the screws 420 and respective springs. By gently tightening the screws 420 and releasing the micro-stage, the load is gradually transferred from the micro-stage to the screws 420 and their respective spring sets, while maintaining full contact between the CNTA 430 and the top plate 410. In the third step, the required pressure is adjusted by further tightening the screws 420. As a result, the respective springs are compressed to an extent that provides the pressure designated for a specific load experiment.

Although the invention is described herein with reference to the preferred embodiment, one skilled in the art will readily appreciate that other applications may be substituted for those set forth herein without departing from the spirit and scope of the present invention. Accordingly, the invention should only be limited by the Claims included below.

1. An apparatus for the self-adjustment of a first surface to a second surface comprising:
a plurality of rods;
a mounting structure to which said plurality of rods are secured; and
a first spring mounted to said mounting structure by means of a center screw, the mounting allowing said spring to pivot;
wherein said mounting structure is secured over said second surface, and wherein said first surface is inserted within said mounting structures between said spring and said second surface.

2. The apparatus of claim 1, wherein said spring is mounted at a center point of said mounting structure.

3. The apparatus of claim 1, further comprising:
a second spring, mounted in an essentially similar manner as said first spring, to said mounting structure.

4. The apparatus of claim 1, wherein said center screw is turnable to cause said spring to increase or decrease pressure on said first surface.

5. The apparatus of claim 1, said center screw is turnable to cause said first surface to self-adjust such that it is essentially parallel with said second surface.

6. The apparatus of claim 1, said second surface comprising a hot surface.

7. The apparatus of claim 6, said hot surface comprising a heat sink element associated with an integrated circuit.

8. The apparatus of claim 1, wherein said first surface comprises a heat sink.

9. The apparatus of claim 8, wherein said heat sink further comprises:
a carbon nano-tube array (CNTA) facing said second surface.

10. The apparatus of claim 9, wherein turning of said center screw causes said nano-tubes of said CNTA to buckle and thereby increase the effective contact area of said CNTA to said second surface.

11. The apparatus of claim 10, wherein said contact area comprises a heat dissipation contact area.

12. The apparatus of claim 1, said spring further comprising any one of: a plurality of prongs, a disk.

13. The apparatus of claim 1, further comprising at least two rods.

14. The apparatus of claim 1, said mounting structure further comprising any one of: a plurality of prongs, a plate.

15. The apparatus of claim 1, wherein said plurality of rods are mounted to a base surface to which said second surface is mounted directly or indirectly.

16. The apparatus of claim 15, said base surface comprising a printed circuit board (PCB).

17. A method for constructing a structure for self-adjustment of a first surface to a second surface, comprising the steps of:
affixing a plurality of rods to a mounting structure;
pivotably affixing a first spring to said mounting structure;
affixing the compound structure comprising said mounting structure, said plurality of rods, and said first spring to a base surface; and
inserting a first surface between said spring and said base surface.

18. The method of claim 17, further comprising the step of:
affixing said spring to essentially the center of said mounting structure.

19. The method of claim 17, further comprising the step of:
affixing a second spring, mounted in an essentially similar manner as said first spring, to said mounting structure.

20. The method of claim 17, further comprising the step of:
affixing said compound structure over a second surface mounted directly or indirectly onto said base surface.

21. The method of claim 20, further comprising the step of:
turning a center screw affixing said spring to said mounting structure to apply pressure onto said first surface and cause said first surface to essentially self-adjust with said second surface.

22. The method of claim 21, said first surface comprising a carbon nano tube array (CNTA) mounted to enable said CNTA to come into contact with said second surface upon application of pressure to said first surface.

23. The method of claim 22, further comprising the step of:
applying pressure to said first surface by means of said center screw until a plurality of said carbon nano-tubes of said CNTA buckle.

24. The method of claim 20, said second surface comprising a hot surface.

25. The method of claim 24, said hot surface comprising a heat sink of an integrated circuit (IC).

26. The method of claim 17, said base surface comprising a printed circuit board (PCB).

27. An apparatus for self-adjustment of a load, cell comprising:
a first plate;
a second plate;
a plurality of screws for tightening said first plate to said second plate;
a specimen surface between said first plate and said second plate; and
a load cell adapted to measure pressure, said load cell having a rounded portion, said load cell inserted between said specimen surface and said second plate with said rounded portion facing towards said second plate;
wherein tightening of said plurality of screws causes said specimen surface and said load cell to self-adjust to said first plate and said second plate.

28. The apparatus of claim 27, wherein said specimen surface comprises a carbon nano-tube array (CNTA).

29. The apparatus of claim 27, further comprising means coupled to said load cell for any of measuring pressure on said load cell and displaying pressure measured by said cell load.

30. A method for self-adjustment of a specimen surface and a load cell, comprising the steps of:
mounting a first plate and a second plate to each other with a plurality of screws;
inserting a specimen surface in a gap between said first plate and said second plate;
inserting between said specimen surface and said second plate a load cell the load cell having a rounded portion, the rounded portion facing said second plate; and
tightening said plurality of screws to cause self-adjustment of said specimen surface and said load cell to said first plate and said second plate.

31. The method of claim 30, further comprising the step of:
connecting said load cell to means for any of measuring pressure on said load cell and displaying pressure measured by said cell load.

32. The method of claim 30, further comprising the step of:
affixing to said specimen surface a carbon nano-tube array (CNTA).
